(19) United States
(12) Patent Application Publication
(10) Pub. No.: US 2026/0165219 A1
(43) Pub. Date: Jun. 11, 2026

(54) METHOD OF MANUFACTURING SEMICONDUCTOR DEVICE INCLUDING BONDING OF SUBSTRATE STRUCTURES

(71) Applicant: SK hynix Inc., Gyeonggi-do (KR)

(72) Inventor: Hwan Young KIM, Gyeonggi-do (KR)

(21) Appl. No.: 19/207,402

(22) Filed: May 14, 2025

(30) Foreign Application Priority Data
Dec. 11, 2024 (KR) 10-2024-0184166

(51) Int. Cl. H01L 23/00; H01L 25/18; H10B 80/00; H10D 80/30

(52) U.S. Cl. CPC H10W 99/00; H10B 80/00; H10D 80/30; H10W 72/90; H10W 80/016; H10W 80/102; H10W 80/312; H10W 80/327; H10W 80/334; H10W 80/341; H10W 90/00; H10W 90/792

(57) ABSTRACT

In a method of manufacturing a semiconductor device according to an embodiment of the present disclosure, a first substrate structure including a first connection pad and a second substrate structure including a second connection pad are prepared. A surface of at least one of the first and second connection pads is charged with a negative charge. The first and second substrate structures are heat-treated while the first and second connection pads are in contact with each other for bonding the first and second substrate structures to each other.

### CROSS-REFERENCE TO RELATED APPLICATIONS

The present application claims priority under 35 U.S. C § 119(a) to Korean Application No. 10-2024-0184166, filed on Dec. 11, 2024, the entire contents of which are incorporated herein by reference.

### BACKGROUND

### 1. Technical Field

Embodiments of the present disclosure generally relate to a method of manufacturing a semiconductor device, and more particularly, to a method of manufacturing a semiconductor device including a process of bonding substrate structures.

### 2. Related Art

As semiconductor devices tend to become lighter, thinner, and smaller, a method of forming different integrated circuits on two substrates and bonding the two substrates together to manufacture a semiconductor device has recently emerged, unlike the process of forming integrated circuits on a single substrate. The method of bonding the two substrates to each other can be achieved by forming a metal bonding pad exposed to the outside on uppermost portions of the two substrates, and directly bonding a pair of the metal bonding pads.

### SUMMARY

In a method of manufacturing a semiconductor device according to an embodiment of the present disclosure, a first substrate structure including a first connection pad and a second substrate structure including a second connection pad are prepared. A surface of at least one of the first and second connection pads is charged with a negative charge. The first and second substrate structures are heat-treated while the first and second connection pads are in contact with each other to bond the first and second substrate structures to each other.

In a method of manufacturing a semiconductor device according to an embodiment of the present disclosure, a first substrate structure including a first connection pad and a second substrate structure including a second connection pad are prepared. A surface of at least one of the first and second connection pads is charged with a positive charge. The first and second substrate structures are heat-treated while the first and second connection pads are in contact with each other to bond the first and second substrate structures to each other.

These and other features and advantages of the embodiments of the present disclosure will become better understood from the detailed description and the following drawings.

### BRIEF DESCRIPTION OF THE DRAWINGS

FIG. 1 is a schematic flowchart illustrating a method of manufacturing a semiconductor device according to an embodiment of the present disclosure.

FIG. 2 to FIG. 6 are schematic cross-sectional views illustrating a method of manufacturing a semiconductor device according to an embodiment of the present disclosure.

FIG. 7 and FIG. 8 are schematic cross-sectional views illustrating a method of manufacturing a semiconductor device according to an embodiment of the present disclosure.

FIG. 9 is a schematic flowchart of a method of manufacturing a semiconductor device according to an embodiment of the present disclosure.

FIG. 10 is a schematic cross-sectional view illustrating a method of manufacturing a semiconductor device according to an embodiment of the present disclosure.

FIG. 11 is a schematic cross-sectional view illustrating a method of manufacturing a semiconductor device according to an embodiment of the present disclosure.

FIG. 12 to FIG. 14 are schematic cross-sectional views illustrating a method of manufacturing a semiconductor device according to an embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, an expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

Terms used in the specification of the present application are terms selected in consideration of functions in the presented embodiments, and the meaning of the terms may vary depending on the intention or custom of a user or operator in the technical field. The meanings of the terms used follow the definitions defined when specifically defined herein, and may be interpreted as meanings generally recognized by those skilled in the art in the absence of specific definitions.

In addition, when describing a manufacturing method, each process constituting the manufacturing method may be performed in a different order from the stated order unless a specific order is clearly stated in the context. That is, each process may be performed sequentially in the same order as the stated order or may be performed substantially simultaneously, and at least some processes may be performed in a different order.

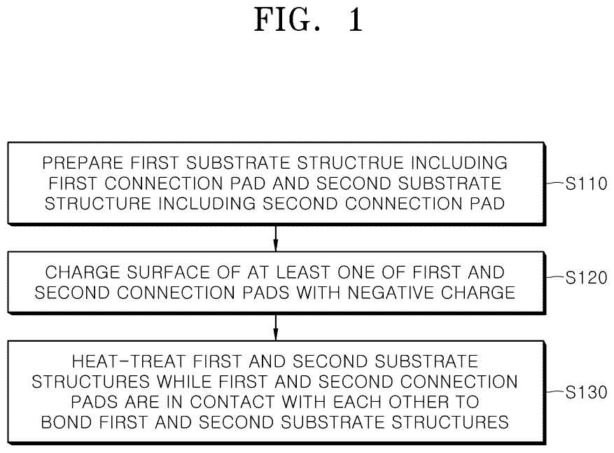

FIG. 1 is a schematic flowchart illustrating a method of manufacturing a semiconductor device according to an embodiment of the present disclosure. The method of manufacturing the semiconductor device includes forming different substrate structures and bonding the different substrate structures to each other.

Referring to operation S110 of FIG. 1, a first substrate structure including a first connection pad and a second substrate structure including a second connection pad are prepared. In an embodiment, preparing the first substrate structure may include forming a first device structure on a first substrate and forming the first connection pad on the first device structure. The first connection pad may be exposed to the outside from an upper portion of the first device structure. The first connection pad may include metal. In addition, preparing the first substrate structure may further include forming a first bonding insulation layer laterally adjacent to the first connection pad. The first bonding insulation layer may include oxide, oxynitride, or a combination of two or more thereof. In an embodiment, preparing the second substrate structure may include forming a second device structure on the second substrate, and forming a second connection on the second device structure. The second connection pad may be exposed to the outside from an upper portion of the second device structure. The second connection pad may include metal. In addition, preparing the second substrate structure may further include forming a second bonding insulation layer laterally adjacent to the second connection pad. The second bonding insulation layer may include oxide, oxynitride, or a combination of two or more thereof.

Referring to operation S120 of FIG. 1, a surface of at least one of the first and second connection pads is charged with a negative charge. In an embodiment, charging the surface of the at least one connection pad with a negative charge may include generating negative ions by using a negative ion generator and exposing at least one of the first and second substrate structures to the negative ions to provide the negative ions to the at least one connection pad. In another embodiment, charging the surface of the at least one connection pad with the negative charge may include selecting at least one substrate structure from the first and second substrate structures, electrically connecting a bias applying device to the at least one connection pad of the at least one substrate structure, and applying a negative bias to the at least one connection pad through the bias applying device, such that the surface of the at least one connection pad maintains a negative potential.

In some embodiments, when charging the surface of at least one of the connection pads with the negative charge, a process of charging the surface of at least one bonding insulation layer that is laterally adjacent to the at least one connection pad with the negative charge may be additionally performed.

Referring to operation S130 of FIG. 1, the first and second substrate structures are heat-treated while the first and second connection pads are in contact with each other, thereby bonding the first and second substrate structures.

In an embodiment, the first and second substrate structures are heat-treated at a temperature ranging from above room temperature to 300° C. As used herein, the term “room temperature” refers to a temperature in the range of about 20° C. to about 25° C., unless otherwise specified. As an example, the heat-treatment may be performed at a temperature ranging from above 25° C. to 300° C. Compared to a case where the process of charging the surface of at least one connection pad with a negative charge is omitted, when the process of charging the surface with a negative charge as in operation S120 is performed, the heat-treatment temperature for bonding the first and second substrate structures can be lowered. The method of charging the surface of at least one connection pad with a negative charge can provide a driving force required for metal atoms within the at least one connection pad to diffuse for bonding the substrates.

In an embodiment, when charging the surface of the at least one connection pad with the negative charge by applying the negative bias, heat-treating the first and second substrate structures may be performed while applying the negative bias to the at least one connection pad.

In some embodiments, bonding the first and second substrate structures may include forming a first bond between the first connection pad and the second connection pad and forming a second bond between the first bonding insulation layer and the second bonding insulation layer.

In some embodiments, the method may further include, prior to the operation S120, cleaning the surfaces of the first and second connection pads by plasma treatment.

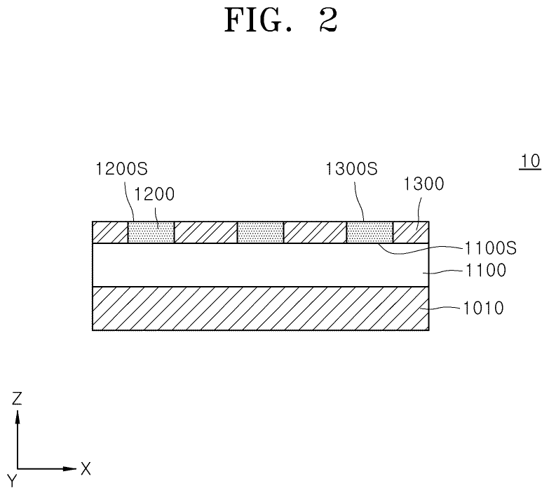

FIG. 2 to FIG. 6 are schematic cross-sectional views illustrating a method of manufacturing a semiconductor device according to an embodiment of the present disclosure. The method of manufacturing the semiconductor device described with reference to FIGS. 2 to 6 may include operations S110 to S130 illustrated in the flowchart of FIG. 1.

Referring to FIG. 2, a first substrate structure 10 including first connection pads 1200 is prepared. The first substrate structure 10 may be formed over a first substrate 1010 through the following processes. The first substrate 1010 may be made of various materials that can be subjected to semiconductor integration processes. For example, the first substrate 1010 may be a semiconductor substrate, a conductor substrate, or an insulator substrate. In an embodiment, the first substrate 1010 may be a semiconductor substrate. The semiconductor substrate may include an n-type or a p-type doped well region.

A first device structure 1100 may be formed on the first substrate 1010. The first device structure 1100 may include a plurality of levels of conductive layers, conductive contact patterns interconnecting the plurality of levels of conductive layers, and interlayer insulation layers disposed between the plurality of levels of conductive layers. In an embodiment, the first device structure 1100 may include various integrated circuits. The integrated circuits may include a memory cell circuit, a peripheral logic circuit, or a wiring circuit. For example, the integrated circuits may include a field effect transistor, a resistor element, a capacitor, or a combination of two or more thereof. The first device structure 1100 may be formed through a semiconductor integration process.

Next, the first connection pads 1200 may be formed on the first device structure 1100. The first connection pads 1200 may be exposed to the outside. In this context, “the outside” refers to areas external to the internal structures or layers of the semiconductor device. Specifically, the first connection pads 1200 being “exposed to the outside” means that they are accessible from the external surface of the semiconductor device, allowing for physical or electrical connection to other systems, such as external circuits, substrates, or interfacing hardware. The first connection pads 1200 may be electrically connected to the integrated circuits of the first device structure 1100. In addition, a first bonding insulation layer 1300 may be formed adjacent to the first connection pads 1200 in a lateral direction, for example, in the x-direction. As illustrated in FIG. 2, the first connection pads 1200 and the first bonding insulation layer 1300 may contact each other in the lateral direction on the same plane 1100S.

In an embodiment, a conductive material layer including a metal may be formed on the first device structure 1100, and the conductive material layer may be patterned to form the first connection pads 1200. The first bonding insulation layer 1300 may be formed by filling spaces between the first connection pads 1200 on the first device structure 1100 with an insulating material. In this case, a planarization process may be performed so that a surface 1200S of the first connection pads 1200 and a surface 1300S of the first bonding insulation layer 1300 are positioned at the same level.

In another embodiment, an insulating material layer may be formed on the first device structure 1100, and the insulating material layer may be patterned to form the first bonding insulation layer 1300 including contact hole patterns. Next, the contact hole patterns may be filled with a conductive material including metal to form the first connection pads 1200. In this case, a planarization process may be performed so that the surface 1200S of the first connection pads 1200 and the surface 1300S of the first bonding insulation layer 1300 are positioned at the same level.

The first connection pad 1200 may include, for example, copper (Cu), a binary copper alloy, a quaternary or higher high-entropy alloy (HEA), or a combination of two or more thereof. The binary copper alloy may include, for example, a copper-titanium (Cu—Ti) alloy or a copper-aluminum (Cu—Al) alloy. The quaternary or higher high-entropy alloy may include, for example, at least four or more metals selected from copper (Cu), nickel (Ni), iron (Fe), chromium (Cr), platinum (Pt), silver (Ag), palladium (Pd), cobalt (Co), titanium (Ti), zirconium (Zr), and hafnium (Hf). The four or more metals can be maintained in a state of being mixed in substantially equal amounts within the high-entropy alloy. In an embodiment, the high-entropy alloy may be a single phase solid state solution including the metal of the quaternary or higher system. The first bonding insulation layer 1300 may include, for example, an oxide, an oxynitride, or a combination of two or more thereof.

The first substrate structure 10 may be formed through the processes of the various embodiments described above.

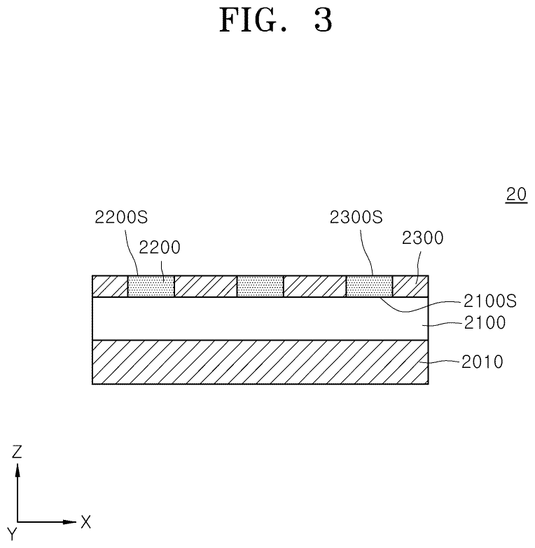

Referring to FIG. 3, a second substrate structure 20 including second connection pads 2200 is prepared. A method of forming the second substrate structure 20 may be the same or substantially the same as the method of manufacturing the first substrate structure 10 described above with reference to FIG. 1.

Specifically, a second substrate 2010 is prepared. The second substrate 2010 may be made of substantially the same material as the first substrate 1010. Subsequently, a second device structure 2100 may be formed on the second substrate 2010. The second device structure 2100 may include a plurality of levels of conductive layers, conductive contact patterns connecting the multiple levels of conductive layers to each other, and interlayer insulation layers disposed between the plurality of levels of conductive layers. In an embodiment, the second device structure 2100 may include various integrated circuits such as, for example, a memory cell circuit, a peripheral logic circuit, or a wiring circuit. In an embodiment, the second device structure 2100 may include at least one different integrated circuit from the integrated circuits of the first device structure 1100. In an embodiment, the second device structure 2100 may include different integrated circuits from the integrated circuits of the first device structure 1100. For example, when the integrated circuit of the first device structure 1100 includes a memory cell circuit, the integrated circuit of the second device structure 2100 may include a peripheral logic circuit that drives the memory cell circuit.

Next, the second connection pads 2200 may be formed on the second device structure 2100. The second connection pads 2200 may be exposed to the outside. The second connection pads 2200 may be electrically connected to the integrated circuits of the second device structure 2100. In addition, a second bonding insulation layer 2300 may be formed adjacent to the second connection pads 2200 in a lateral direction, for example, in the x-direction. The second connection pads 2200 and the second bonding insulation layer 2300 may be made of substantially the same material as the first connection pads 1200 and the first bonding insulating layer 1300, respectively.

As illustrated in FIG. 3, the second connection pads 2200 and the second bonding insulation layer 2300 may contact each other in the lateral direction on the same plane. A surface 2200S of the second connection pads 2200 and a surface 2300S of the second bonding insulation layer 2300 may be positioned on the same level.

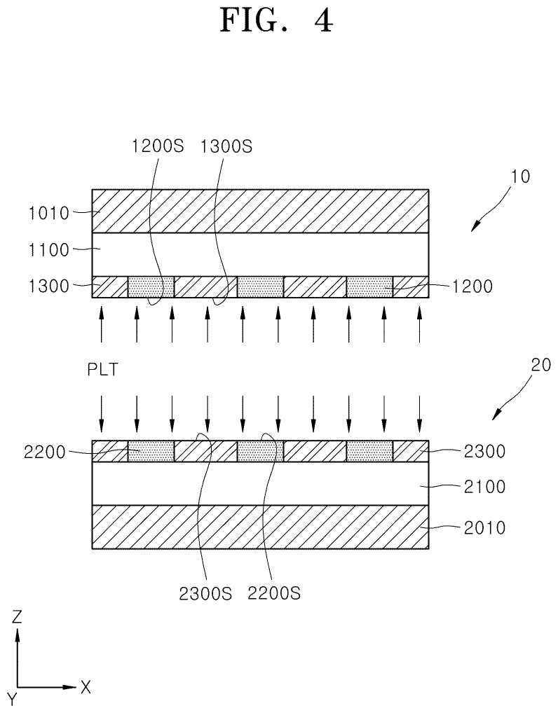

Referring to FIG. 4, the first connection pads 1200 of the first substrate structure 10 may be cleaned by performing plasma treatment (PLT) for the surface 1200S of the first connection pad 1200. Through the plasma treatment (PLT), impurities such as an oxide film formed on the surface 1200S of the first connection pads 1200 are removed. For the plasma treatment (PLT), a reaction gas such as nitrogen (N₂), nitric oxide (N₂O), ammonia (NH₃), hydrogen (H₂), etc. may be provided.

The plasma treatment (PLT) may also be performed on the first bonding insulation layer 1300 for removing the impurities formed on the surface 1300S of the first bonding insulation layer 1300.

In the same manner, the plasma treatment (PLT) may be performed on the second connection pads 2200 of the second substrate structure 20. The plasma treatment (PLT) may also be performed on the second bonding insulation layer 2300 adjacent to the second connection pads 2200.

Referring to FIG. 4, the plasma treatment (PLT) may be performed while the first and second substrate structures 10 and 20 are positioned apart from each other. In this case, the first connection pads 1200 and the second connection pads 2200 are positioned facing each other and the first and second bonding insulation layers 1300 and 2300 are positioned facing each other. The plasma treatment (PLT) may be performed while the first substrate structure 10 and the second substrate structure 20 are positioned together in a plasma chamber.

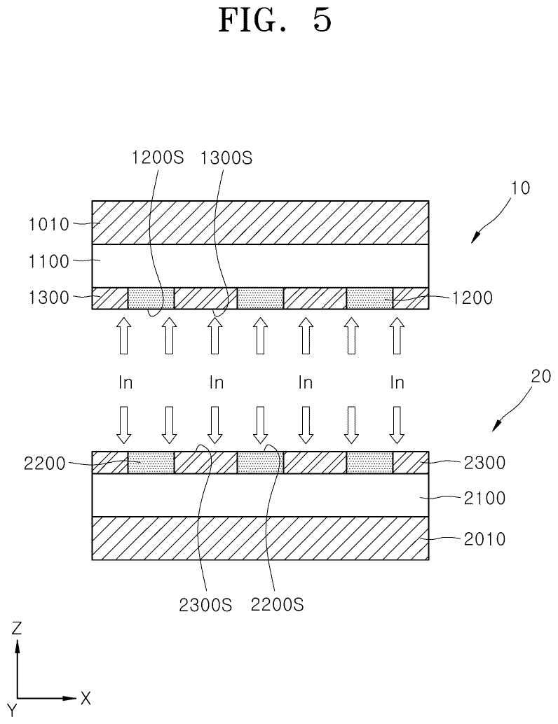

Referring to FIG. 5, the first substrate structure 10 and the second substrate structure 20 may be disposed spaced apart from each other in the z-direction. Subsequently, negative ions In may be provided to the first substrate structure 10 and the second substrate structure 20, so that the surfaces 1200S and 2200S of the first and second connection pads 1200 and 2200 and the surfaces 1300S and 2300S of the first and second bonding insulation layers 1300 and 2300 may be charged with negative charges, respectively.

In an embodiment, the negative ions In may be provided through a negative ion generator. The negative ion generator ionizes gas molecules through corona discharge and collects the negative ions In among the ionized gas molecules by filtering the ionized gas molecules inside the negative ion generator. Then the negative ion generator provides the collected negative ions into the first and second connection pads 1200 and 2200 and the first and second bonding insulation layers 1300 and 2300.

The negative ions In may be attached to the surfaces of the first and second connection pads 1200 and 2200 and transfer the electrons to the metal in regions which are adjacent to the surfaces of the first and second connection pads 1200 and 2200. That is, the electrons may be transferred to the metal positioned at a depth from the surfaces of the first and second connection pads 1200 and 2200. The metal may be charged with the negative charge by the electrons. That is, the surfaces of the first and second connection pads 1200 and 2200 being charged with the negative charge means that the metals of the surfaces of the first and second connection pads 1200 and 2200 and the regions adjacent to the surfaces are charged with the negative charge.

The negative ions In that transfer the electrons may be converted into neutral gas species. Some of the converted neutral gas species may remain attached to the surfaces of the first and second connection pads 1200 and 2200. However, the attached neutral gas species might not alter the negative charge states of the surfaces of the first and second connection pads 1200 and 2200. Some of the converted neutral gas species may be detached from the first and second connection pads 1200 and 2200. The detached neutral gas species may be released through outgassing.

The first and second connection pads 1200 and 2200 are configured so that the electrons received from the negative ions In are not discharged outside of the first and second substrate structures 10 and 20, respectively. For example, the first and second connection pads 1200 and 2200 may be electrically isolated from the integrated circuits of the first and second device structures 1100 and 2100 to be disposed to maintain an electrically floating state. In another embodiment, the first and second connection pads 1200 and 2200 are configured to be electrically connected to the integrated circuits of the first and second device structures 1100 and 2100, but not directly connected to a ground line, so that the electrons are not discharged through the ground line.

According to an embodiment, when the surfaces 1200S and 2200S of the first and second connection pads 1200 and 2200 are charged with the negative charge, bonding energy between metal elements in the surfaces 1200S and 2200S of the first and second connection pads 1200 and 2200 and internal regions adjacent to the surfaces 1200S and 2200S, respectively, may be reduced.

For example, bonding between metal atoms may occur on the surface of the first connection pad 1200 and in an internal region adjacent to the surface, and the electrons may be disposed in an orbital generated during the bonding between the metal atoms. When the surface of the first connection pad 1200 is charged with the negative charge, in the bond between the metal atoms, the orbital in which the electrons transferred from the negative ions are disposed may be an orbital having a higher energy level than the orbital in which the electrons are disposed in the bond between the metal atoms when the surface of the first connection pad 1200 is in a neutral state. Accordingly, in the internal region of the first connection pad 1200 adjacent to the surface of the first connection pad 1200, a bonding length between the metal atoms may be increased. As the bonding length between the metal atoms is increased, the bonding energy of the metal atoms in the surface of the first connection pad 1200 and the internal region adjacent to the surface may be decreased. Similarly, when the surface of the second connection pad 2200 is negatively charged (i.e., charged with the negative charge), the bonding length between the metal atoms in the surface of the second connection pad 2200 and an internal region of the second connection pad 2200 adjacent to the surface may be increased. In addition, the bonding energy of the metal atoms in the surface of the second connection pad 2200 and the internal region adjacent to the surface may be decreased.

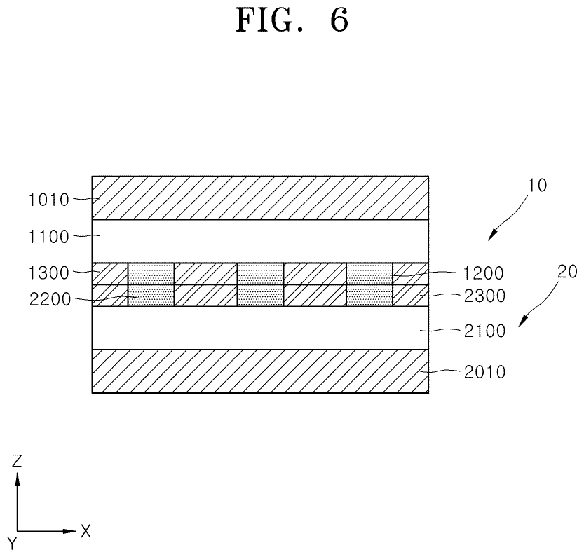

Accordingly, when the surfaces 1200S and 2200S of the first and second connection pads 1200 and 2200 are charged with the negative charge, respectively, in the bonding process of the first and second substrate structures 10 and 20 described with reference to FIG. 6 below, the metal atoms located on the surfaces of the first and second connection pads 1200 and 2200 and the internal regions adjacent to the surfaces can break the bonds between the metal atoms and more readily diffuse between the first and second connection pads 1200 and 2200.

According to an embodiment, when the surfaces of the first and second bonding insulation layers 1300 and 2300 are charged with the negative charge, diffusion of oxygen may be activated at the surfaces of the first and second bonding insulation layers 1300 and 2300 and also in the internal regions which are adjacent to these surfaces.

Each of the first and second bonding insulation layers 1300 and 2300 may include oxide, oxynitride, or a combination of two or more thereof. When the surfaces of the first and second bonding insulation layers 1300 and 2300 are charged negatively, the possibility that oxygen within the oxide or oxynitride can be ionized at the surfaces of the first and second bonding insulation layers 1300 and 2300 and in the regions adjacent to the surfaces may be increased significantly. The ionized oxygen may include an ion of an oxygen molecule, for example, O₂⁻, O₂²⁻, or an ion of an oxygen atom, for example, O⁻, O²⁻.

The ions of the oxygen molecules and/or of the oxygen atoms can reduce the bonding energy of oxygen in the oxide or oxynitride. In addition, the ions of the oxygen atoms may have a lower barrier energy resisting diffusion in the oxide or oxynitride than the oxygen atoms in a neutral state.

Accordingly, when the surfaces of the first and second bonding insulation layers 1300 and 2300 are charged negatively, in the bonding process of the first and second substrate structures 10 and 20 described with reference to FIG. 6 below, oxygen located on the surfaces of the first and second bonding insulation layers 1300 and 2300 and in the internal regions which are adjacent to the surfaces can relatively easily diffuse between the first and second bonding insulation layers 1300 and 2300 in the form of ions of oxygen atoms by breaking the bonds within the oxide or the oxynitride.

Referring to FIG. 6, the first and second substrate structures 10 and 20 may be heat-treated while the first and second connection pads 1200 and 2200 are in contact with each other and the first and second bonding insulation layers 1300 and 2300 are in contact with each other. As a result, the first and second substrate structures 10 and 20 are bonded to each other.

During the heat-treatment of the first and second substrate structures 10 and 20, the metal atoms may mutually diffuse between the first connection pad 1200 and the second connection pad 2200, and the oxygen ions may mutually diffuse between the first connection pad 1200 and the second connection pad 2200. As a result of the mutual diffusion of the metal atoms and the oxygen ions, a first bonding region of the first connection pad 1200 and the second connection pad 2200 and a second bonding region of the first bonding insulation layer 1300 and the second bonding insulation layer 2300 may be formed, and the first and second substrate structures 10 and 20 may be bonded to each other. As described above, the first bonding region may correspond to a mutual diffusion region of the metal atoms of the first and second connection pads 1200 and 2200, and the second bonding region may correspond to a mutual diffusion region of the oxygen ions of the first and second bonding insulation layers 1300 and 2300.

In an embodiment, the heat treatment of the first and second substrate structures 10 and 20 may induce metal recrystallization in the first bonding region of the first and second connection pads 1200 and 2200. For example, the metal recrystallization may proceed as follows. During the heat treatment process, deformation energy may be accumulated in the metal crystal in the region where the metal atoms are mutually diffused. When the accumulated deformation energy reaches a critical value, as the deformation energy is released from the metal crystal, new metal crystal grains may be formed. A size of the metal crystal grain generated by the recrystallization may be smaller than the size of the metal crystal grain of the same region before the recrystallization. In addition, the size of the metal crystal grain generated by the recrystallization may be smaller than the size of the metal crystal grain in the regions of the first and second connection pads 1200 and 2200 which are located outside the first bonding region and where the recrystallization does not occur. The size of the metal crystal grain after the metal recrystallization may have a size of, for example, 1 nm to 20 nm.

In an embodiment, the heat treatment process for the first and second substrate structures 10 and 20 may be performed at a temperature ranging from, for example, above room temperature to 300° C. The temperature of the heat treatment process of the first and second substrate structures 10 and 20 according to an embodiment may be lower than the temperature of the heat treatment process required to bond the first and second substrate structures 10 and 20 when, as a comparative example, the process of charging with a negative charge described with reference to FIG. 5 is omitted.

In some embodiments, the plasma treatment PLT for the first and second substrate structures 10 and 20 described with reference to FIG. 4 may be omitted. In another embodiment, the plasma treatment PLT may be performed on only one of the first and second substrate structures 10 and 20.

In some embodiments, the process of charging with a negative charge described with reference to FIG. 5 may be performed by selecting one of the first and second substrate structures 10 and 20 and performing the process on the selected substrate structure. For example, when the first substrate structure 10 is selected from the first and second substrate structures 10 and 20, the surfaces of the first connection pad 1200 and the first bonding insulation layer 1300 may be charged with a negative charge. In this case, the process of charging the surfaces of the second connection pad 2200 and the second bonding insulation layer 2300 of the second substrate structure 20 with a negative charge may be omitted.

As described above, according to an embodiment of the present disclosure, the bonding process for the first and second substrate structures may be performed after charging the surfaces of the connection pad and the bonding insulation layer of at least one of the first and second substrate structures with a negative charge. When the connection pad is charged with the negative charge, diffusion reaction of metal atoms within the connection pad and diffusion reaction of oxygen ions within the bonding insulation layer may be activated, thereby improving the efficiency of the bonding process between the first and second substrate structures. For example, the bonding process can be performed at a lower process temperature compared to the conventional method.

As a comparative example of the present disclosure, instead of the method of providing negative ions In described with reference to FIG. 5, the surfaces 1200S and 2200S of the first and second connection pads 1200 and 2200 and the surfaces 1300S and 2300S of the first and second bonding insulation layers 1300 and 2300 may be charged with electric charges, respectively, through plasma treatment. In the plasma treatment, negative charge and positive charge may be provided together to the surfaces 1200S and 2200S of the first and second connection pads 1200 and 2200 and the surfaces 1300S and 2300S of the first and second bonding insulation layers 1300 and 2300, respectively. In this case, the negative and positive charges may cancel each other out during the plasma treatment, thereby reducing the efficiency of electric charge charging. In addition, by the plasma treatment, regions charged with the negative charge and regions charged with the positive charge may exist in the surfaces 1200S and 2200S of the first and second connection pads 1200 and 2200 and the surfaces 1300S and 2300S of the first and second bonding insulation layers 1300 and 2300, respectively. Accordingly, the homogeneity and uniformity of the electric charge charging may be relatively deteriorated.

As the efficiency, homogeneity, and uniformity of the electric charge charging are deteriorated, in the case of the comparative example, the concentration of the metal atoms diffused mutually during the heat treatment may be relatively decreased. As a result, the size of the deformation energy that causes the metal recrystallization is reduced, so that the size of the metal crystal grain after the metal recrystallization according to the comparative example may be greater than the size of the metal crystal grain after the metal recrystallization according to the embodiment.

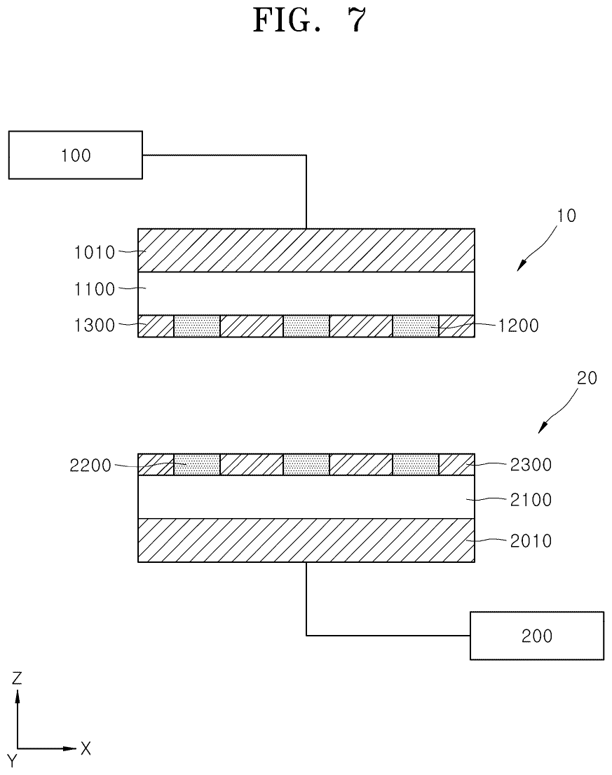

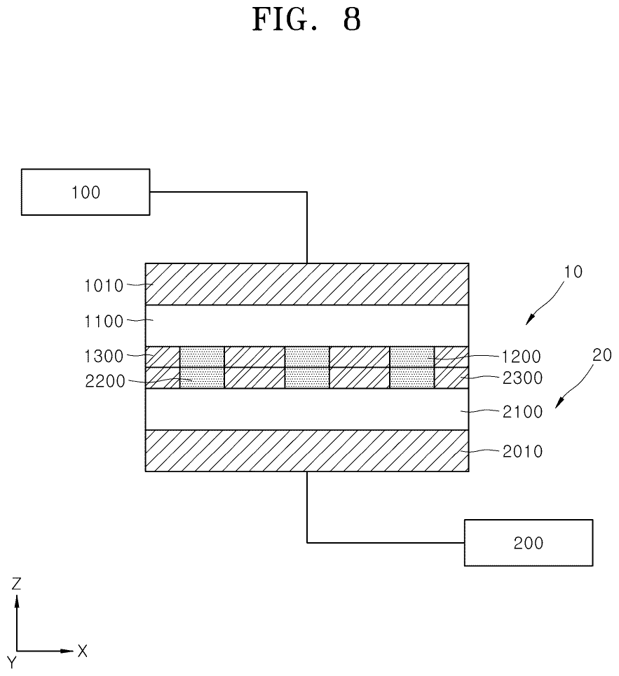

FIG. 7 and FIG. 8 are schematic cross-sectional views illustrating a method of manufacturing a semiconductor device according to an embodiment of the present disclosure.

First, the processes described with reference to FIG. 2 to FIG. 4 are performed to prepare first and second substrate structures 10 and 20, and plasma treatment (PLT) is performed on the first and second substrate structures 10 and 20. In some embodiments, the plasma treatment (PLT) may be omitted.

Referring to FIG. 7, the first and second substrate structures 10 and 20 may be disposed spaced apart from each other in the z-direction. First and second bias applying devices 100 and 200 are prepared. The first bias applying device 100 may be electrically connected to a first connection pad 1200 of the first substrate structure 10. For example, the first bias applying device 100 may be electrically connected to the first connection pad 1200 via a well region of a first substrate 1010 and wirings of a first device structure 1100.

In addition, the second bias applying device 200 may be electrically connected to a second connection pad 2200 of the second substrate structure 20. The second bias applying device 200 may be electrically connected to the second connection pad 2200 via the well region of a second substrate 2010 and the wirings of a first device structure 2100.

Referring to FIG. 8, the first and second substrate structures 10 and 20 may be disposed such that the first and second connection pads 1200 and 2200 contact each other and first and second bonding insulation layers 1300 and 2300 contact each other. A negative bias may be applied to the first connection pad 1200 through the first bias applying device 100. By the applied negative bias, a surface 1200S of the first connection pad 1200 may maintain a negative potential. Accordingly, the surface 1200S of the first connection pad 1200 may be charged with a negative charge. In the same manner, the negative bias is applied to the second connection pad 2200 through the second bias applying device 200. By the applied negative bias, a surface 2200S of the second connection pad 2200 maintains a negative potential. Accordingly, the surface 2200S of the second connection pad 2200 is charged with a negative charge.

Because each of the first and second bonding insulation layers 1300 and 2300 includes an insulator, a negative charge charging phenomenon caused by the negative bias application might not occur. However, partial charging may occur in surface regions of the first and second bonding insulation layers 1300 and 2300, adjacent to the first and second connection pads 1200 and 2200, respectively, due to the effect of the negative bias application.

In an embodiment, as the method of applying the negative bias, for example, an RF bias method, an AC bias method, a DC bias method, a pulse bias method, or a combination of two or more thereof may be used.

In some embodiments, when applying the negative bias to the first and second connection pads 1200 and 2200 through the first and second bias applying devices 100 and 200, respectively, the magnitudes of the negative biases applied to the first and second connection pads 1200 and 2200 may be controlled to be different from each other. By applying negative biases of different magnitudes the surfaces of the first and second connection pads 1200 and 2200 can maintain different negative potentials and, the amounts of the negative charge charged to the surfaces of the first and second connection pads 1200 and 2200 may be different from each other. Accordingly, as described below, during heat treatment for the first and second substrate structures 10 and 20 described later, the position or thickness of the bonding region of the first and second connection pads 1200 and 2200 can be controlled.

Next, the first and second substrate structures 10 and 20 are heat treated while the negative bias is applied to the first and second connection pads 1200 and 2200. During the heat treatment for the first and second substrate structures 10 and 20, metal atoms are diffused between the first and second connection pads 1200 and 2200 to form a first bonding region of the first and second connection pads 1200 and 2200. In addition, through the heat treatment, a second bonding region of the first and second bonding insulation layers 1300 and 2300 are formed.

In an embodiment, the heat treatment for the first and second substrate structures 10 and 20 may induce metal recrystallization in the first bonding region of the first and second connection pads 1200 and 2200. For example, the metal recrystallization may proceed as follows. During the heat treatment process, deformation energy is accumulated in the metal crystals in the region where the metal atoms are mutually diffused. When the accumulated deformation energy reaches a critical value, the deformation energy may be released from the metal crystals to form new metal crystal grains. A size of the metal crystal grain formed by the recrystallization may be smaller than the size of the metal crystal grain in the same region before the recrystallization. In addition, the size of the metal crystal grain generated by the recrystallization may be smaller than the size of the metal crystal grain within the regions of the first and second connection pads 1200 and 2200 which are located outside the first bonding region and where the recrystallization does not occur.

In an embodiment, a process of heat treating the first and second substrate structures 10 and 20 may be performed at a temperature ranging from, for example, above room temperature to 300° C. The temperature of the heat treatment process for the first and second substrate structures 10 and 20 according to an embodiment may be lower than a heat treatment temperature required for bonding the first and second substrate structures 10 and 20 when the process of applying the negative bias described with reference to FIG. 8, as a comparative example, is omitted.

In some embodiments, the process of charging with the negative charge described with reference to FIG. 7 and FIG. 8 may be performed by selecting one of the first and second substrate structures 10 and 20 and performing the process on the selected substrate structure. For example, when the first substrate structure 10 is selected from the first and second substrate structures 10 and 20, the negative bias is applied to the first connection pad 1200 and the surface of the first connection pad 1200 is charged with the negative charge. The process of applying the negative bias to the second connection pad 2200 of the second substrate structure 20 may be omitted. Subsequently, the heat treatment process for the first and second substrate structures 10 and 20 is performed while the negative bias is applied only to the first connection pad 1200.

As a comparative example of the present disclosure, instead of the method of applying the negative bias described with reference to FIG. 7 and FIG. 8, the surfaces 1200S and 2200S of the first and second connection pads 1200 and 2200, respectively, may be charged with electric charges through plasma treatment. As previously discussed, as the electric charges for charging, the plasma treatment provides both positive and negative charges. Subsequently, the metal charged by the positive and negative charges may be diffused between the first and second connection pads 1200 and 2200 during the heat treatment to form the bonding region.

The depth at which the positive charge and the negative charge penetrate through the plasma treatment is 20 nm to 30 nm from the surfaces 1200S and 2200S of the first and second connection pads 1200 and 2200, respectively. Accordingly, the metal charged with the positive charge and the negative charge may be a metal in a region located within a depth of 20 nm to 30 nm from the surfaces 1200S and 2200S of the first and second connection pads 1200 and 2200, respectively.

On the other hand, according to an embodiment of the present disclosure, the depth of the region where the negative charges are distributed, provided by the method of applying the negative bias, may exceed 30 nm from the surfaces 1200S and 2200S of the first and second connection pads 1200 and 2200, respectively. Accordingly, in the case of the embodiment of the present disclosure, the region where the metal atoms capable of mutual diffusion are distributed by the heat treatment may extend deeper from the surfaces 1200S and 2200S of the first and second connection pads 1200 and 2200, respectively, compared to the case of the comparative example. As a result, the first bonding region of the first and second connection pads 1200 and 2200 according to the embodiment of the present disclosure may be located in a deeper region from the surfaces 1220S and 2220S of the first and second connection pads 1220 and 2220, respectively, than the first bonding region of the first and second connection pads 1200 and 2200 according to the comparative example.

Accordingly, the region where the metal recrystallization occurs according to the embodiment of the present disclosure may extend deeper from the surfaces 1200S and 2200S of the first and second connection pads 1200 and 2200, respectively, than the region where the metal recrystallization occurs according to the comparative example. For example, according to the embodiment of the present disclosure, the metal recrystallization may occur within a region of a depth from the surfaces of the first and second connection pads 1200 and 2200, wherein the depth may be greater than 30 nm. In addition, the size of the metal crystal grain after the metal recrystallization may be 1 nm to 20 nm.

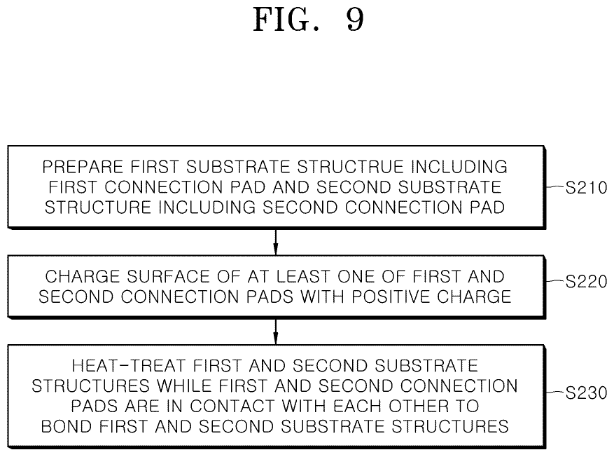

FIG. 9 is a schematic flowchart illustrating a method of manufacturing a semiconductor device according to an embodiment of the present disclosure. The method of manufacturing the semiconductor device of FIG. 9 may be different from the method of manufacturing the semiconductor device described with reference to FIG. 1 in that the process of charging the surface of the connection pad with a positive charge of S220 may be different.

Referring to S210 of FIG. 9, a first substrate structure including a first connection pad and a second substrate structure including a second connection pad are prepared. The first and second connection pads may be disposed to be exposed to the outside from the first and second substrate structures, respectively. The configuration of S210 may be the same or substantially the same as the configuration of S110 of FIG. 1.

Referring to S220 of FIG. 9, a surface of at least one of the first and second connection pads is charged with a positive charge. In an embodiment, charging the surface of the at least one connection pad with the positive charge may include generating positive ions using a positive ion generator, and exposing at least one of the first and second substrate structures to the positive ions, thereby providing the positive ions to the at least one connection pad. In another embodiment, charging the surface of the at least one connection pad with the positive charge may include operations of selecting at least one substrate structure from the first and second substrate structures, electrically connecting a bias applying device to the at least one connection pad of the at least one substrate structure, and applying a positive bias to the at least one connection pad through the bias applying device so that the surface of the at least one connection pad maintains a positive potential.

In some embodiments, when charging the surface of at least one connection pad with the positive charge, a process of charging a surface of at least one bonding insulation layer that is laterally adjacent to the at least one connection pad with the positive charge may be additionally performed.

Referring to S230 of FIG. 9, the first and second substrate structures are bonded to each other by heat-treating the first and second substrate structures while the first and second connection pads are in contact with each other. A configuration of S230 may be the same or substantially the same as the configuration of S130 of FIG. 1.

Compared to the case where the process of charging the surface of at least one of the connection pads with a positive charge is omitted, in the case of the embodiment of the present disclosure, when performing S230, the heat treatment temperature for bonding the first and second substrate structures can be lowered. The method of charging the surface of at least one of the connection pads with a positive charge can provide a driving force required for metal atoms within the at least one connection pad to diffuse for bonding between substrates.

In an embodiment, when the surface of the at least one connection pad is charged with the positive charge by applying the positive bias, heat-treating the first and second substrate structures may be performed while applying the positive bias to the at least one connection pad.

In some embodiments, prior to the operation S220, cleaning the surfaces of the first and second connection pads through plasma treatment may be further included.

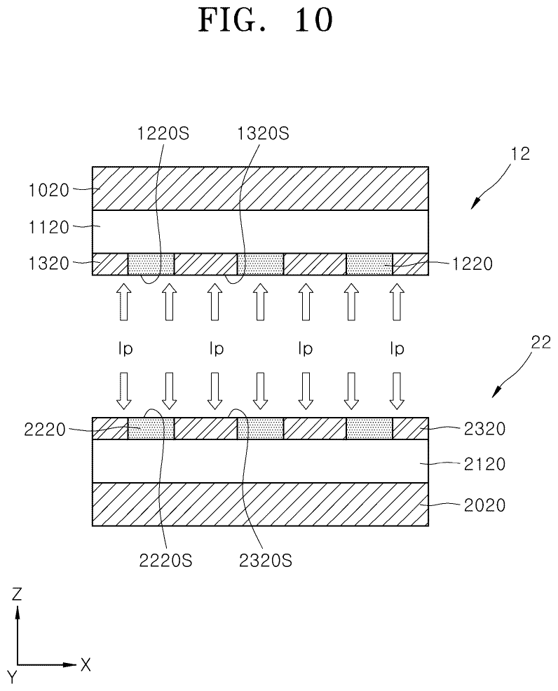

FIG. 10 is a schematic cross-sectional view illustrating a method of manufacturing a semiconductor device according to an embodiment of the present disclosure. The method of manufacturing the semiconductor device described with reference to FIG. 10 may include operations S210 to S230 illustrated in the flowchart of FIG. 9.

The method includes preparing first and second substrate structures 12 and 22 according to the process described with reference to FIGS. 2 and 3. The first substrate structure 12 includes a first device structure 1120 disposed on a first substrate 1020, a first connection pad 1220 and a first bonding insulation layer 1320 disposed on the first device structure 1120. The second substrate structure 22 includes a second device structure 1120 disposed on a second substrate 2020, a second connection pad 1220 and a second bonding insulation layer 1320 disposed on the second device structure 1120. The configurations of the first and second substrate structures 12 and 22 may be the same or substantially the same as the configurations of the first and second substrate structures 10 and 20 of FIGS. 2 and 3, respectively.

Next, the process described with reference to FIG. 4 may be performed including performing plasma treatment (PLT) on the first and second substrate structures 12 and 22. However, in some embodiments, the plasma treatment (PLT) may be omitted.

Referring to FIG. 10, the first and second substrate structures 12 and 22 may be spaced apart from each other in the z-direction. Positive ions Ip are provided into the first and second substrate structures 12 and 22 to charge the surfaces 1220S and 2220S of the first and second connection pads 1220 and 2220 and also the surfaces 1320S and 2320S of the first and second bonding insulation layers 1320 and 2320 with a positive charge, respectively.

In an embodiment, the positive ions Ip may be provided through a positive ion generator. The positive ion generator ionizes gas molecules through corona discharge and filters and collects the positive ions Ip among the ionized gas molecules inside the positive ion generator. The positive ion generator is configured to provide the collected positive ions Ip to the first and second connection pads 1220 and 2220 and the first and second bonding insulation layers 1320 and 2320.

The positive ions Ip may receive electrons from the metal in regions adjacent to the surfaces of the first and second connection pads 1220 and 2220 after being attached to the surfaces of the first and second connection pads 1220 and 2220. As the metal provides the electrons to the positive ions Ip, the surfaces of the first and second connection pads 1220 and 2220 may be charged with the positive charges. That is, the positive ions (Ip) can take electrons from the metal near the surfaces of the first and second connection pads 1220 and 2220 after attaching to these surfaces. When the metal supplies electrons to the positive ions, the surfaces of the connection pads 1220 and 2220 become positively charged.

The positive ions Ip that receive the electrons may be converted into neutral gas species. Some of the neutral gas species may remain attached to the surfaces of the first and second connection pads 1220 and 2220. However, the attached neutral gas species might not alter the positive charge states of the surfaces of the first and second connection pads 1220 and 2220. Some of the neutral gas species may be detached from the first and second connection pads 1220 and 2220. The detached neutral gas species may be released through outgassing.

The first and second connection pads 1220 and 2220 may be configured to maintain the charged state with the positive charge. For example, the first and second connection pads 1220 and 2220 are disposed to be electrically isolated from the integrated circuits of the first and second device structures 1120 and 2120, respectively, thereby maintaining an electrically floating state. In another embodiment, the first and second connection pads 1220 and 2220 may be configured to be electrically connected to the integrated circuits of the first and second device structures 1120 and 2120, respectively, but are not directly connected to a ground line, so that electrons are not provided to the first and second connection pads 1120 and 2220 through the ground line.

According to an embodiment, when the surfaces 1220S and 2220S of the first and second connection pads 1220 and 2220 are charged with positive charges, the bonding energy between metal elements in the internal regions adjacent to the surfaces 1220S and 2220S of the first and second connection pads 1220 and 2220 may be reduced, compared to the case where the surfaces 1220S and 2220S of the first and second connection pads 1220 and 2220 maintain electrically neutral states, respectively. When the surfaces of the first and second bonding insulation layers 1320 and 2320 are charged with positive charges, the bonding energy of oxygen located in the internal regions adjacent to the surfaces of the first and second bonding insulation layers 1320 and 2320 may decrease, compared to the case where the surfaces of the first and second bonding insulation layers 1320 and 2320 are maintained in an electrically neutral state.

Next, using the heat-treatment as described with reference to FIG. 6, the first and second substrate structures 12 and 22 of FIG. 10 are heat-treated while the first and second connection pads 1220 and 2200 are in contact with each other and the first and second bonding insulation layers 1320 and 2320 are in contact with each other. As a result, the first and second substrate structures 12 and 22 are bonded to each other.

In an embodiment, when the surfaces 1220S and 2220S of the first and second connection pads 1220 and 2220 are positively charged, the heat-treatment process applied to the first and second substrate structures 12 and 22 may cause metal bonds between the metal atoms located in the internal regions adjacent to the surfaces of the first and second connection pads 1220 and 2220 to break. As a result, metal atoms released from the broken bonds may more readily diffuse between the first and second connection pads 1220 and 2220. In addition, when the surfaces of the first and second bonding insulation layers 1320 and 2320 are positively charged, the heat-treatment process applied to the first and second substrate structures 12 and 22 may cause oxygen bonds between the oxygen located in the internal regions adjacent to the surfaces of the first and second bonding insulation layers 1320 and 2320 to break. As a result, oxygen released from the broken oxygen bonds may more readily diffuse between the first and second bonding insulation layers 1320 and 2320. The oxygen may diffuse in the form of ions of oxygen atoms.

As a result, a first bonding region is formed between the first and second connection pads 1220 and 2220. Also, a second bonding region is formed between the first and second bonding insulation layers 1320 and 2320. Thus, the first and second substrate structures 12 and 22 are bonded to each other through the first and second bonding regions.

According to a comparative example of the present disclosure, instead of the method of providing the positive ions Ip described with reference to FIG. 10, the surfaces 1220S and 2220S of the first and second connection pads 1220 and 2220 and the surfaces 1320S and 2320S of the first and second bonding insulation layers 1320 and 2320 may be charged with electric charges, respectively, through plasma treatment. As described above, the plasma treatment may provide negative and positive charges together to the surfaces 1220S and 2220S of the first and second connection pads 1220 and 2220 and the surfaces 1320S and 2320S of the first and second bonding insulation layers 1320 and 2320, respectively. Accordingly, the efficiency, homogeneity, and uniformity of charge charging can be relatively degraded.

As the efficiency, homogeneity and uniformity of the charge charging are degraded, according to the method of the comparative example, the concentration of metal atoms that are mutually diffused during heat-treatment may be relatively reduced. As a result, the magnitude of the deformation energy causing metal recrystallization is reduced, so that the size of the metal crystal grain after metal recrystallization according to the comparative example may be larger than the size of the metal crystal grain after metal recrystallization according to an embodiment.

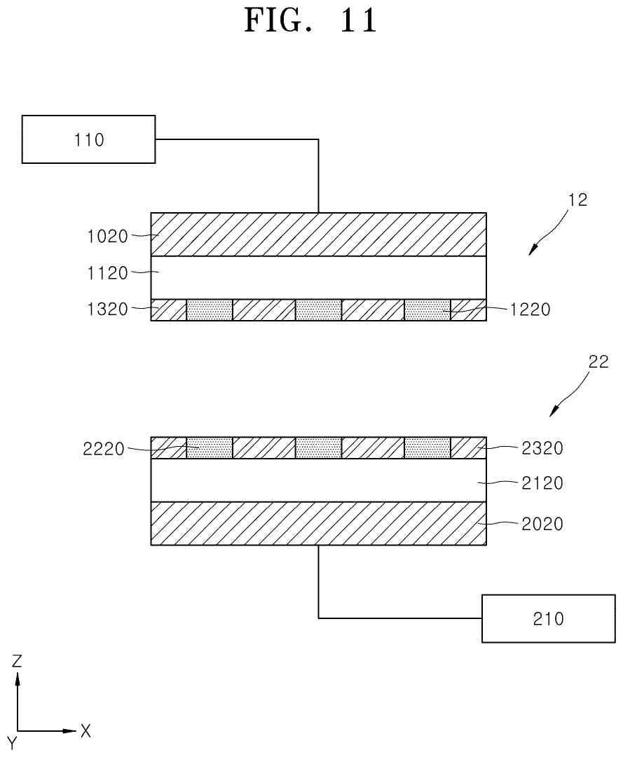

FIG. 11 is a schematic cross-sectional view illustrating a method of manufacturing a semiconductor device according to an embodiment of the present disclosure.

Referring to FIG. 11, the method of manufacturing a semiconductor device is different from the method of manufacturing the semiconductor device, described with reference to FIG. 10, in that the method of charging the surfaces 1220S and 2220S of the first and second connection pads 1220 and 2220 of the first and second substrate structures 12 and 22 with positive charges, respectively is different from that of the method of manufacturing the semiconductor device, described with reference to FIG. 10.

First and second substrate structures 12 and 22 on which the processes described with reference to FIG. 2 to FIG. 4 may be performed are spaced apart from each other in the z-direction. First and second bias applying devices 110 and 210 are prepared. The first bias applying device 110 is electrically connected to a first connection pad 1220 of the first substrate structure 12, and the second bias applying device 210 is electrically connected to a second connection pad 2220 of the second substrate structure 22.

Next, as described with reference to FIG. 8, the first and second substrate structures 12 and 22 may be disposed such that the first and second connection pads 1220 and 2220 contact each other and first and second bonding insulation layers 1320 and 2320 contact each other. Then, a bias is applied to the first and second connection pads 1220 and 2220 through the first and second bias applying devices 110 and 210, respectively. In this case, unlike what was described with reference to FIG. 8, a positive bias may be applied to the first connection pad 1220 through the first bias applying device 110. Because of the applied positive bias, a surface 1220S of the first connection pad 1220 maintains a positive potential and the surface 1220S of the first connection pad 1220 is charged with a positive charge. Similarly, a positive bias is applied to the second connection pad 2220 through the second bias applying device 210. Because of the applied positive bias, a surface 2220S of the second connection pad 2220 maintains a positive potential, and the surface 2220S of the second connection pad 2220 is charged with a positive charge.

Because each of the first and second bonding insulation layers 1320 and 2320 includes an insulator, a phenomenon of the first and second bonding insulation layers 1320 and 2320 being charged with positive charges by the positive bias application may not occur. However, in the surface regions of the first and second bonding insulation layers 1320 and 2320 which are adjacent to the first and second bonding pads 1220 and 2220, respectively, partial charging may occur due to the effect of the positive bias application.

In an embodiment, the method of applying the positive bias may include, for example, an RF (radio frequency) bias method, an AC (alternating current) bias method, a DC (direct current) bias method, a pulse bias method, or a combination of two or more thereof.

In some embodiments, when applying the positive bias to the first and second connection pads 1220 and 2220 through the first and second bias applying devices, respectively, the magnitudes of the positive biases applied to the first and second connection pads 1220 and 2220 may be different. For example, the magnitude of the bias applied to one of the first and second connection pads 1220 and 2220 may be 1.5 to 5 times greater than that applied to the other. As a result, the surfaces of the first and second connection pads 1220 and 2220 may maintain different positive potentials and the amounts of positive charges charged on the surfaces of the first and second connection pads 1220 and 2220 may be different.

As the magnitude of the applied bias increases, the amount of positive charge accumulated on the surfaces of the first and second connection pads 1220 and 2220 may also increase. Furthermore, the depths of regions at which positive charge is accumulated may also increase with the applied bias. Accordingly, the position and/or thickness of the bonding region of the first and second connection pads 1220 and 2220, is determined during the heat-treatment of the first and second substrate structures 12 and 22 which is described later, and may be adjusted. Subsequently, the first and second substrate structures 12 and 22 are heat-treated while the positive bias is applied to the first and second connection pads 1220 and 2220. During the heat-treatment of the first and second substrate structures 12 and 22, metal atoms are diffused between the first and second connection pads 1220 and 2220 to form first bonding regions of the first and second connection pads 1220 and 2220. In addition, through the heat-treatment, second bonding regions of the first and second bonding insulating layers 1320 and 2320 are also formed.

In an embodiment, the process of heat-treating the first and second substrate structures 12 and 22 may be performed at a temperature ranging from, for example, above room temperature to 300° C. Importantly, the heat-treatment temperature for the first and second substrate structures 12 and 22 according to an embodiment may be lower than the heat-treatment temperature required for bonding the first and second substrate structures 12 and 22 when the process of applying the positive bias is omitted, as a comparative example.

In some embodiments, the process of applying the positive bias to charge the surfaces of the connection pads with the positive charge as described with reference to FIG. 11 may include first selecting one of the first and second substrate structures 12 and 22 and then applying the positive bias on the selected substrate structure. Next, the heat-treatment process for the first and second substrate structures 12 and 22 is performed with the positive bias applied only to the selected substrate structure.

As a comparative example of the present disclosure, instead of applying the positive bias as described with reference to FIG. 11, the surfaces 1220S and 2220S of the first and second connection pads 1220 and 2220, respectively, may be charged with electric charges through plasma treatment. As previously discussed, the depth at which the positive charge and the negative charge penetrate through the plasma treatment may be 20 nm to 30 nm from the surfaces 1220S and 2220S of the first and second connection pads 1220 and 2220, respectively. Accordingly, the metals charged with the positive charge and the negative charge may be metals within the region extending to a depth of 20 nm to 30 nm from the surfaces 1220S and 2220S of the first and second connection pads 1220 and 2220, respectively.

On the other hand, according to an embodiment of the present disclosure, the region where the positive charge is distributed may be controlled to be between a depth from the surfaces 1220S and 2220S of the first and second connection pads 1200 and 2220, respectively, by applying the positive bias. In such a case, the depth may be greater than 30 nm. As a result, the bonding region of the first and second connection pads 1220 and 2220 according to an embodiment of the present disclosure can extend to a deeper region from the surfaces 1220S and 2220S of the first and second connection pads 1220 and 2220, respectively, than the bonding region of the first and second connection pads 1220 and 2220 according to one comparative example.

Accordingly, the region where the metal recrystallization occurs according to an embodiment of the present disclosure may extend to a deeper region from the surfaces 1220S and 2220S of the first and second connection pads 1220 and 2220, respectively, than the region where the metal recrystallization occurs according to the comparative example. For example, according to an embodiment of the present disclosure, the metal recrystallization occurs in a region of a depth from the surfaces 1220S and 2220S of the first and second connection pads 1220 and 2220, respectively, wherein the depth may be greater than 30 nm. In addition, according to the method of the preset disclosure, the size of the metal crystal grain after the metal recrystallization may be from 1 nm to 20 nm.

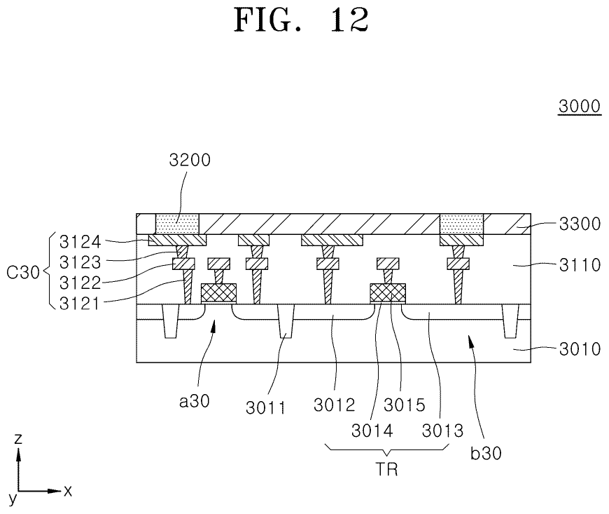

FIG. 12 to FIG. 14 are schematic cross-sectional views illustrating a method of manufacturing a semiconductor device according to an embodiment of the present disclosure. In an embodiment, the semiconductor device 1 manufactured by the method of manufacturing the semiconductor device of FIG. 12 to FIG. 14 may include a plurality of memory cells and a memory cell driving circuit that controls the plurality of memory cells. For example, the semiconductor device 1 may be a NAND type flash memory device having a three-dimensional structure.

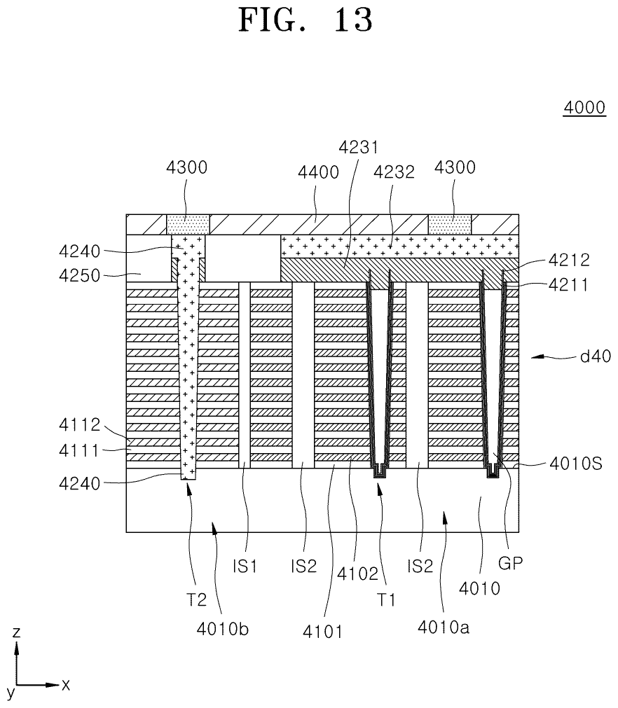

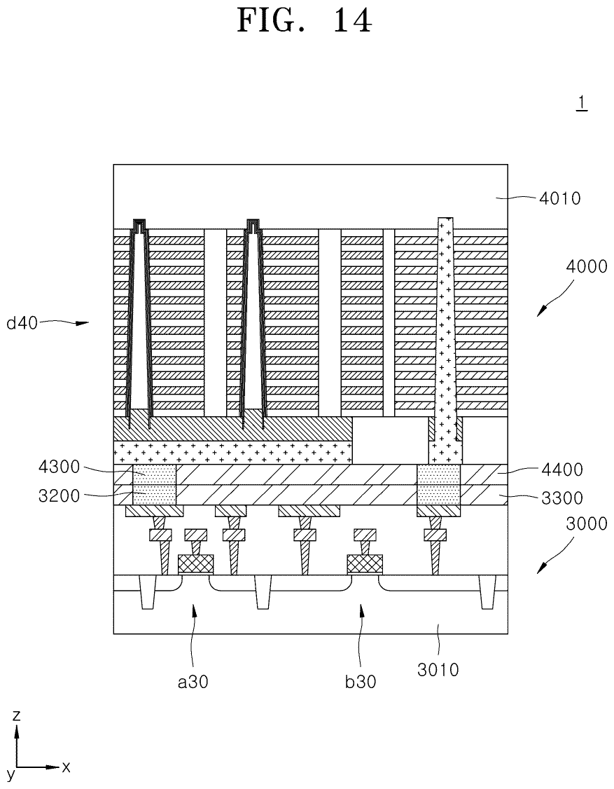

In an embodiment, the method of manufacturing the semiconductor device 1 may include forming a first substrate structure 3000 including memory cell driving circuits a30 and b30, described with reference to FIG. 12, forming a second substrate structure 4000 including a memory cell structure d40, described with reference to FIG. 13, and bonding the first and second substrate structures 3000 and 4000 to each other, described with reference to FIG. 14.

Referring to FIG. 12, the first substrate structure 3000 may be formed on a first substrate 3010 through a semiconductor integration process. The first substrate structure 3000 may include the first substrate 3010, the memory cell driving circuits a30 and b30 as examples of device structures disposed on the first substrate 3010, a driving circuit wiring C30 electrically connected to the memory cell driving circuits a30 and b30 over the substrate 3010, a first connection pad 3200 electrically connected to the driving circuit wiring C30, and a first bonding insulation layer 3300 disposed in a lateral direction, for example, in the x-direction or the y-direction of the first connection pad 3200.

Referring to FIG. 12, the first substrate 3010 may be a known wafer capable of being subjected to a semiconductor integrated circuit process. For example, the first substrate 3010 may be a silicon wafer doped with an n-type or p-type dopant. Although not shown, the first substrate 3010 may have a well region doped with an n-type or p-type dopant. A device isolation film 3011 defining active regions may be formed within the first substrate 3010. The device isolation film 3011 may include an oxide film, a nitride film, or a combination thereof.

In an embodiment, the memory cell driving circuits a30 and b30 may include a source line driving circuit a30 connected to a source line of the memory cell and a page buffer circuit b30 which is a peripheral circuit of the memory cell. Each of the source line driving circuit a30 and the page buffer circuit b30 may include a field effect transistor TR including first and second well regions 3012 and 3013, a gate dielectric layer 3014, and a gate electrode layer 3015. One of the first and second well regions 3012 and 3013 may function as a source region of the field effect transistor TR, and the other one may function as a drain region.

Referring to FIG. 12, an interlayer insulation layer 3110 may be disposed on the first substrate 3010. The interlayer insulation layer 3110 may cover the memory cell driving circuits a30 and b30. The interlayer insulation layer 3110 may include at least one insulation layer. The driving circuit wiring C30 may be disposed inside the interlayer insulation structure 3110. The driving circuit wiring C30 may include first and second circuit pattern layers 3122 and 3124 and first and second contact plugs 3121 and 3123. The first and second circuit pattern layers 3122 and 3124 may be disposed on different planes. The first contact plug 3121 may electrically connect the first circuit pattern layer 3122 to the first and second well regions 3012 and 3013. The second contact plug 3123 may electrically connect the first and second circuit pattern layers 3122 and 3124 to each other.

Referring to FIG. 12, the first connection pad 3200 may be disposed on the second circuit pattern layer 3124. The first connection pad 3200 is electrically connected to the second circuit pattern layer 3124. The cross-sectional area of the first connection pad 3200 may be smaller than the cross-sectional area of the second circuit pattern layer 3124. A configuration of the first connection pad 3200 may be the same or substantially the same as the configuration of the first connection pad 1200 described with reference to FIG. 2. The first bonding insulation layer 3300 may be disposed on the interlayer insulation layer 3110 and surround the first connection pad 3200. A configuration of the first bonding insulation layer 3300 may be the same or substantially the same as the configuration of the first bonding insulation layer 1300 described with reference to FIG. 2. A top surface of the first bonding insulation layer 3300 may be co-planar with the top surface of the first connection pad 3200.

Referring to FIG. 13, the second substrate structure 4000 may be fabricated on a second substrate 4010 through a semiconductor integration process. The second substrate structure 4000 may include the second substrate 4010, the memory cell structure d40 as a device structure disposed on the second substrate 4010, a second connection pad 4300 disposed over the memory cell structure d40, and cell wirings 4231, 4232, and 4240 electrically connecting the memory cell structure d40 to the second connection pad 4300. Additionally, the second substrate structure 4000 may include a second bonding insulation layer 4400 disposed in a lateral direction, for example, in the x-direction or y-direction, of the second connection pad 4300.

Referring to FIG. 13, the second substrate 4010 may be a known wafer capable of being subjected to a semiconductor integrated circuit process. For example, the second substrate 4010 may be a silicon wafer doped with an n-type or p-type dopant. Although not shown, the second substrate 4010 may have a well region doped with an n-type or p-type dopant.

The memory cell structure d40 may be disposed over the second substrate 4010. The memory cell structure d40 may include a cell gate structure 4010a and a contact plug structure 4010b that are spaced apart from each other in a lateral direction, for example, in the x-direction or y-direction, parallel to a surface 4010S of the second substrate 4010. A first vertical insulation structure IS1 may be formed between the cell gate structure 4010a and the contact plug structure 4010b. The first vertical insulation structure IS1 may separate the cell gate structure 4010a from the contact plug structure 4010b. A second vertical insulation structure IS2 may be formed between adjacent cell gate structures 4010a for isolating the adjacent cell gate structures 4010a from each other.

The cell gate structure 4010a may include interlayer insulation layers 4101 and gate electrode layers 4102 that are alternately stacked in the z-direction perpendicular to the surface 4010S of the second substrate 4010. The memory cell structure d40 may include a memory function layer 4211 and a channel layer 4212 that are disposed on a sidewall of a trench T1 which is passing through the cell gate structure 4010a and exposes the second substrate 4010.

Although not shown, the memory function layer 4211 may include a barrier insulation layer, a charge storage layer, and a charge tunnel layer that are sequentially formed from a sidewall of the trench T1. The channel layer 4212 may be formed on a sidewall of the memory function layer 4211 and protrude upwardly from the cell gate structure 4010a. The trench T1 in which the memory function layer 4211 and the channel layer 4212 are formed may be filled with an insulating gap fill material GP.

Common source line structures 4231 and 4232 may be disposed as a cell wiring over the cell gate structure 4010a. For example, the common source line structures 4231 and 4232 may include a first conductor layer 4231 which is a doped semiconductor layer and a second conductor layer 4232 which is a metal layer. Because the first conductor layer 4231 is in contact with the channel layer 4212, the common source line structures 4231 and 4232 may be electrically connected to the channel layer 4212.

The contact plug structure 4010b may include interlayer insulation layers 4111 and sacrificial insulation layers 4112 that are alternately stacked in the z-direction perpendicular to the surface 4010S of the substrate 4010. The interlayer insulation layers 4111 may be disposed at the same level as the interlayer insulation layer 4101 of the cell gate structure 4010a. The sacrificial insulation layers 4112 may be disposed at the same levels as the gate electrode layers 4102 of the cell gate structure 4010a.

The memory cell structure d40 may include a vertical contact plug 4240 that fills a trench T2 which is passing through the contact plug structure 4010b and exposes the second substrate 4010. The vertical contact plug 4240 may extend over the contact plug structure 4010b. A passivation layer 4250 may surround the upper portion of the vertical contact plug 4240 to electrically insulate the vertical contact plug 4240 from the common source line structures 4231 and 4232. The passivation layer 4250 is positioned between the top surface of the stack of the alternating interlayer insulation layers 4111 and the sacrificial insulation layers 4112 and the second bonding insulation layer 4400 in a vertical direction (i.e., in z-direction).

Referring to FIG. 13, the second connection pad 4300 may be disposed on the cell wirings 4231, 4232, and 4240. A configuration of the second connection pad 4300 may be the same or substantially the same as the configuration of the second connection pad 2200 described with reference to FIG. 3. The second bonding insulation layer 4400 is disposed to surround the second connection pad 4300 on the cell wirings 4231, 4232, and 4240. A configuration of the second bonding insulation layer 4400 may be the same or substantially the same as the configuration of the second bonding insulation layer 2300 described with reference to FIG. 3.

Referring to FIG. 14, the first substrate structure 3000 and the second substrate structure 4000 are bonded to form the semiconductor device 1. According to an embodiment, bonding the first and second substrate structures 3000 and 4000 may include cleaning the surfaces of the exposed first connection pad 3200 and the first bonding insulation layer 3300 of the first substrate structure 3000, for example, through plasma treatment. Also, the surfaces of the exposed first connection pad 4300 and the first bonding insulation layer 4400 of the second substrate structure 4000 are cleaned through plasma treatment. The plasma treatment method may be the same or substantially the same as the plasma treatment (PLT) method described with reference to FIG. 4.

In an embodiment, negative ions may be provided to the first and second connection pads 3200 and 4300 and the first and second bonding insulation layers 3300 and 4400 to charge the surfaces of the first and second connection pads 3200 and 4300 and the surfaces of the first and second bonding insulation layers 3300 and 4400 with negative charges. The method of charging the surfaces using the negative ions may be the same as the method of providing the negative ions generated by the negative ion generator which was described with reference to FIG. 5. Next, while the first and second connection pads 3200 and 4300 and the first and second bonding insulation layers 3300 and 4400 are charged with the negative charges, the first and second substrate structures 3000 and 4000 are brought into contact. In this case, the first and second connection pads 3200 and 4300 are brought into contact with each other Also, the first and second bonding insulation layers 3300 and 4400 are brought into contact with each other. As described with reference to FIG. 6, the first and second substrate structures 3000 and 4000 are bonded to each other through heat-treatment at a temperature ranging from above a room temperature to 300° C. while the first and second substrate structures 3000 and 4000 are in contact with each other.

In another embodiment, positive ions may be provided to the first and second connection pads 3200 and 4300 and the first and second bonding insulation layers 3300 and 4400 to charge the surfaces of the first and second connection pads 3200 and 4300 and the surfaces of the first and second bonding insulation layers 3300 and 4400 with positive charges. As the method of charging the surface using the positive ions, a method of providing positive ions generated by the positive ion generator as described with reference to FIG. 10 may be applied. Next, while the first and second connection pads 3200 and 4300 and the first and second bonding insulation layers 3300 and 4400 are charged with the positive charges, the first and second substrate structures 3000 and 4000 are brought into contact. In this case, the first and second connection pads 3200 and 4300 may contact each other, and the first and second bonding insulation layers 3300 and 4400 may contact each other. In a state in which the first and second substrate structures 3000 and 4000 are in contact with each other, the first and second substrate structures 3000 and 4000 may be bonded to each other through heat-treatment at room temperature to 300° C., as described with reference to FIG. 10.

In another embodiment, a negative bias may be applied to the first and second connection pads 3200 and 4300 to charge the surfaces of the first and second connection pads 3200 and 4300 with negative charges. As the method of charging the surfaces by applying the negative bias, the method of applying the negative bias using the bias applying device described with reference to FIG. 7 and FIG. 8 may be applied.

In a state in which the first and second connection pads 3200 and 4300 contact each other and the first and second bonding insulation layers 3300 and 4400 contact each other, the first and second substrate structures 3000 and 4000 are bonded to each other through heat-treatment at room temperature to 300° C., as described with reference to FIG. 8. The heat-treatment may be performed while the negative bias is applied to the first and second connection pads 3200 and 4300.

In another embodiment, a positive bias may be applied to the first and second connection pads 3200 and 4300 to charge the surfaces of the first and second connection pads 3200 and 4300 with positive charges. As the method of charging the surfaces by applying the positive bias, a method of applying a positive bias using the bias applying device described with reference to FIG. 11 may be applied.

In a state in which the first and second connection pads 3200 and 4300 contact each other and the first and second bonding insulation layers 3300 and 4400 contact each other, the first and second substrate structures 3000 and 4000 are bonded to each other through heat-treatment at room temperature to 300° C., as described with reference to FIG. 11. The heat-treatment may be performed while the positive bias is applied to the first and second connection pads 3200 and 4300.

By applying the above-described method, the semiconductor device 1 according to an embodiment of the present disclosure can be manufactured. The semiconductor device 1 includes first and second substrate structures 3000 and 4000 bonded to each other. The first substrate structure 3000 includes a first substrate 3010, memory cell driving circuits a30 and b30 disposed on the first substrate 3010, and a first connection pad 3200 disposed over the first substrate 3010 and electrically connected to the memory cell driving circuits a30 and b30. The second substrate structure 4000 includes a second substrate 4010, a memory cell structure d40 disposed on the second substrate 4010, and a second connection pad 4300 disposed over the second substrate 4010 and electrically connected to the memory cell structure d40.

The technical concepts of the present disclosure are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not considered a restrictive standpoint. The scope of the present disclosure is not limited to the descriptions, and all distinctive features within an equivalent scope should be construed as included in the present disclosure. All changes within the meaning and range of equivalency of the claims are included within the scope of the present disclosure. Furthermore, the embodiments may be combined to form additional embodiments.

What is claimed is:

1. A method of manufacturing a semiconductor device, the method comprising:
preparing a first substrate structure including a first connection pad and a second substrate structure including a second connection pad;
charging a surface of at least one of the first and second connection pads with a negative charge; and
heat-treating the first and second substrate structures while the first and second connection pads are in contact with each other to bond the first and second substrate structures to each other.

2. The method of claim 1, wherein charging the surface of at least one of the first and second connection pads comprises:
generating negative ions using a negative ion generator; and
exposing at least one of the first and second substrate structures to the negative ions to provide the negative ions to the surface of the at least one connection pad.

3. The method of claim 1, wherein heat-treating the first and second substrate structures is performed at a temperature ranging from above room temperature to 300 °C.

4. The method of claim 1, wherein preparing the first substrate structure comprises:
forming a first device structure on a first substrate;
forming the first connection pad on the first device structure; and
forming a first bonding insulation layer laterally adjacent to the first connection pad on the first device structure, and
wherein preparing the second substrate structure comprises:
forming a second device structure on a second substrate;
forming the second connection pad on the second device structure; and
forming a second bonding insulation layer laterally adjacent to the second connection pad on the second device structure.

5. The method of claim 4,
wherein the first device structure includes a memory cell driving circuit disposed on the first substrate, and the first connection pad is electrically connected to the memory cell driving circuit through a driving circuit wiring, and
wherein the second device structure includes a memory cell structure disposed on the second substrate, and the second connection pad is electrically connected to the memory cell structure through a cell wiring.

6. The method of claim 4, further comprising charging a surface of a bonding insulation layer among the first and second bonding insulation layers with the negative charge,
wherein the bonding insulation layer is laterally adjacent to at least one of the connection pads charged with the negative charge.

7. The method of claim 6, wherein charging the bonding insulation layer with the negative charge is performed simultaneously with charging the at least one connection pad with the negative charge.

8. The method of claim 1,
wherein heat-treating the first and second substrate structures comprises inducing metal recrystallization in a bonding region of the first and second connection pads, and
wherein each of metal crystal grains formed by the metal recrystallization has a size of 1 nm to 20 nm.

9. The method of claim 1, wherein charging the surface of the at least one connection pad with the negative charge comprises:
selecting at least one substrate structure among the first and second substrate structures;
preparing a bias applying device to electrically connect the at least one connection pad of the at least one substrate structure with the bias applying device; and
applying a negative bias to the at least one connection pad through the bias applying device to allow a surface of the at least one connection pad to maintain a negative potential.

10. The method of claim 9, wherein heat-treating the first and second substrate structures is performed while the negative bias is applied to the at least one connection pad.

11. The method of claim 9, wherein charging the surface of the at least one connection pad with the negative charge comprises:
electrically connecting the first and second connection pads of the first and second substrate structures with the bias applying device, respectively; and
applying negative biases of different magnitudes to the first and second connection pads through the bias applying device to allow the surfaces of the first and second connection pads to maintain different negative potentials.

12. The method of claim 9, wherein applying the negative bias comprises using at least one of an RF bias method, an AC bias method, a DC bias method, and a pulse bias method.

13. The method of claim 9,
wherein heat-treating the first and second substrate structures comprises inducing metal recrystallization in a bonding region of the first and second connection pads, and
wherein the metal recrystallization occurs from the surface to a depth of greater than 30 nm in each of the first and second connection pads.

14. The method of claim 1, further comprising cleaning the surfaces of the first and second connection pads by plasma treatment, before charging the surface of the at least one connection pad with the negative charge.

15. A method of manufacturing a semiconductor device, the method comprising:
preparing a first substrate structure including a first connection pad and a second substrate structure including a second connection pad;
charging a surface of at least one of the first and second connection pads with a positive charge; and
heat-treating the first and second substrate structures while the first and second connection pads are in contact with each other to bond the first and second substrate structures to each other.

16. The method of claim 15, wherein charging the surface of at least one of the first and second connection pads comprises:
generating positive ions using a positive ion generator; and
exposing the at least one of the first and second substrate structures to the positive ions to provide the positive ions to the surface of the at least one connection pad.

17. The method of claim 15, wherein charging the surface of the at least one connection pad with the positive charge comprises:
selecting at least one substrate structure among the first and second substrate structures;
preparing a bias applying device to electrically connect to the at least one connection pad of the at least one substrate structure with the bias applying device; and
applying a positive bias to the at least one connection pad through the bias applying device to allow the surface of the at least one connection pad to maintain a positive potential.

18. The method of claim 17, wherein heat-treating the first and second substrate structures is performed while the positive bias is applied to the at least one connection pad.

19. The method of claim 17, wherein charging the surface of the at least one connection pad with the positive charge comprises:
electrically connecting to the first and second connection pads of the first and second substrate structures with the bias applying device, respectively; and
applying positive biases of different magnitudes to the first and second connection pads through the bias applying device to allow the surfaces of the first and second connection pads to maintain different positive potentials.

20. The method of claim 15,
wherein the first substrate structure further comprises a first bonding insulation layer that is laterally adjacent to the first connection pad,
wherein the second substrate structure further comprises a second bonding insulation layer that is laterally adjacent to the second connection pad, and
further comprising charging a surface of at least one bonding insulation layer among the first and second bonding insulation layers with the positive charge,
wherein the at least one bonding insulation layer is laterally adjacent to the at least one connection pad charged with the positive charge.
